(19) United States
(12) Patent Application Publication
(10) Pub. No.: US 2002/0052057 A1
(43) Pub. Date: May 2, 2002

(54) Method of fabricating thin film transistor liquid crystal display

(76) Inventor: Jia-Fam Wong, Hsin-Chu-City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,552

(22) Filed: Sep. 19, 2001

(30) Foreign Application Priority Data
Oct. 27, 2000 (TW) 089122668

(51) Int. Cl. H01L 21/00; H01L 21/84

(52) U.S. Cl. 438/30; 438/155; 438/158

(57) ABSTRACT

A method for forming a thin film transistor flat display is disclosed. The flat display includes a glass substrate. A first metal layer is formed on the surface of the glass substrate, the first metal layer is patterned by a first mask to form a gate electrode and a pad electrode. Then, an insulating layer, a semiconductor layer, a doped silicon layer are sequentially formed on the surface of the glass substrate. Further, an active area and a pad opening are defined by a second mask, and then a transparent conductive layer and a second metal layer are formed on the glass substrate. Afterwards, a source electrode and a drain electrode are formed by a third mask in the transistor area and then a passivation layer is formed above the glass substrate. Next, the passivation layer and the second metal layer are patterned by a fourth mask to remove parts of the passivation layer and the second metal layer in the pad opening. Finally, an oxidation reaction is performed to oxide the sidewall surface of the second metal layer uncovered by the passivation layer. When the passivation layer is made by an organic material, a thermal process is used to re-flow the passivation layer and cover the sidewall of the second metal layer.

### BACKGROUND OF INVENTION

1. Field of the Invention

The present invention relates to a method for fabricating a thin film transistor display, and more particularly, to a method for fabricating a thin film transistor display by using fourmasks.

2. Description of the Prior Art

In a thin film transistor liquid crystal display(TFT-LCD), a plurality of pixels are defined and a plurality of thin film transistors (TFT) are arranged in a matrix as switches. These TFTs are used to cooperate with other electrical elements such as capacitors and pads for driving liquid crystal materials in these pixels to produce brilliant images. Each TFT-LCD includes a transparent substrate, a plurality of thin film transistors arranged in a matrix, a pixel electrode, a plurality of signal lines, a plurality of scan lines vertical to the signal lines, a color filter substrate and a liquid crystal material positioned between the transparent substrate and the color filter substrate.

Please refer to FIG. 1 to FIG. 5. FIG. 1 to FIG. 5 are schematic diagrams of a prior art method for fabricating a TFT-LCD. As shown in FIG. 1, the TFT-LCD includes a substrate 10 made by high-purified SiO₂. The substrate 10 has at least one transistor area A and at least one pad area B. The transistor area A is used for forming a transistor 20 on the surface of the substrate 10, and the pad area B is used for forming a pad thereon.

In the prior method, a first metal layer 11 is formed on the transparent substrate 10, and then patterned by a first mask to form a gate electrode 12 on the surface of the transparent substrate 10 in the transistor area A and a pad electrode 14 on the transparent substrate 10 in the pad area B.

Further, as shown in FIG. 2, a chemical vapor deposition process (CVD) is employed to form a layer of silicon nitride on the surface, of the transparent substrate 10. The silicon nitride layer is an insulating layer having a thickness of about 4000 angstroms. Then, a semiconductor layer 18 and a doped silicon layer 22 are formed on the surface of the insulating layer 16.

As shown in FIG. 3, a second mask is used to pattern the doped silicon layer 22 and the semiconductor layer 18 in the transistor area A for defining an active area 23. Then, a third mask is used in the pad area B. An opening 24 is formed by removing a part of the doped silicon layer 22, the semiconductor layer 18 and the insulating layer 16 above the pad electrode 14 in the pad area B. Therefore, the pad electrode 14 is exposed in the opening 24.

As shown in FIG. 4, a transparent conductive layer 25 and a second metal layer 26 are deposited on the surface of the transparent substrate 10. The transparent conductive layer 25 is made of indium tin oxide (ITO) to form a pixel electrode. After that, a fourth mask is used to define a channel 27 in the active region. A part of the second metal layer 26, the transparent conductive layer 25, and the doped silicon layer 22 are removed, and the semiconductor layer 18 above the gate electrode is exposed in the channel 27. The second metal layer 26, the transparent conductive layer 25 and the doped silicon layer 22 are divided into two areas by the channel 27 for forming a source electrode 26a and a drain electrode 26b. Therefore, all main elements of a transistor 20 are formed.

As shown in FIG. 5, finally, a passivation layer 28 is deposited on the surface of the transistor 20 and the pad 30, and fill the channel 27. Then, a fifth mask is used to pattern the passivation layer 28. Parts of the passivation layer 28 and the second metal layer 26 are removed to expose the transparent layer 25 except the transistor area A. Therefore, the manufactured process of the thin film transistor liquid crystal display is completed.

The prior method uses five masks to define the gate electrode, the pad electrode, the active area, the opening in the pad area, the source electrode, the drain electrode and the pixel electrode, respectively. The process of fabricating the thin film transistor liquid crystal display (TFT-LCD) is too complicated and the manufacturing time is too long, therefore, the quality of the TFT-LCD is poor, the cost is high, and further improvements are required.

### SUMMARY OF INVENTION

It is therefore an object of the present invention to provide a method of fabricating a thin film transistor liquid crystal display. The method is used to simplify the process and improve the quality of the display.

The present invention provides a method of fabricating a thin film transistorliquid crystal display. The display is formed on a substrate. The substrate includes a transistor area for forming a transistor and a pad area for forming a pad, respectively. In the beginning, a first metal layer is formed on the surface of the substrate, and then patterned by a first mask to form a gate electrode in the transistor area and a pad electrode in the pad area. After that, an insulating layer, a semiconductor layer and a doped silicon layer are sequentially formed on the substrate. Further, a second mask is used to define a pad opening in the pad area, and also remove the insulating layer, the semiconductor layer, and the doped silicon layer positioned (a) except the transistor area, (b) except the pad area, and (c) within the pad opening. Therefore, the substrate is exposed outside the transistor area and the pad area, and the pad electrode is exposed in the pad opening.

Then, a transparent conductive layer and a second metal layer are formed on the substrate. The transparent conductivity layer and the second metal layer are filled in the pad opening. Afterwards, a third mask is used to pattern the second metal layer. First, a channel is defined in the transistor area and the second metal layer is patterned. Then, utilizing the second metal layer as a mask to remove the transparent conductive layer and the doped silicon layer in the channel so that the semiconductor layer is exposed in the channel. Further, a passivation layer is formed on the substrate and covered the channel. Then, a fourth mask is used to pattern the passivation layer and the second metal layer so as to remove the passivation layer and the second metal layer positioned (a) except the transistor area, (b) except the pad area, and (c) within the pad opening. Therefore, the transparent conductive layer is exposed within the pad opening, and outside the transistor area and the pad area. Finally, a thermal process is performed to re-flow the passivation layer so the passivation layer will cover the transistor area and the sidewall of the second metal area in the pad area. The thermal process is used to prevent the second metal layer from polluting the liquid crystal. Therefore, the process steps will be decreased and quality of the display is also improved.

These and other objectives of the present invention will no doubt become obvious to those of ordinary skill in the art after having read the following detailed description of the preferred embodiment which is illustrated in the various figures and drawings.

### BRIEF DESCRIPTION OF DRAWINGS

FIG. 1 to FIG. 5 are schematic diagrams of a prior art for fabricating a thin film transistor liquid crystal display.

FIG. 6 to FIG. 12 are schematic diagrams of the present invention for fabricating a thin film transistor liquid crystal display.

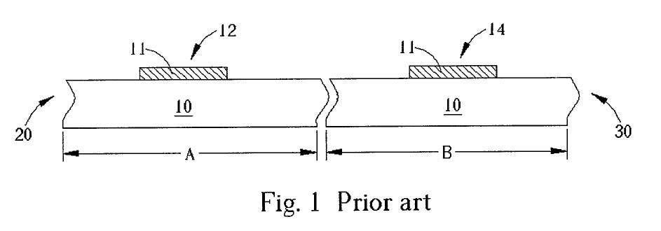

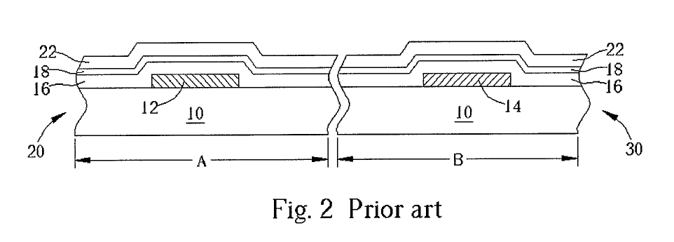

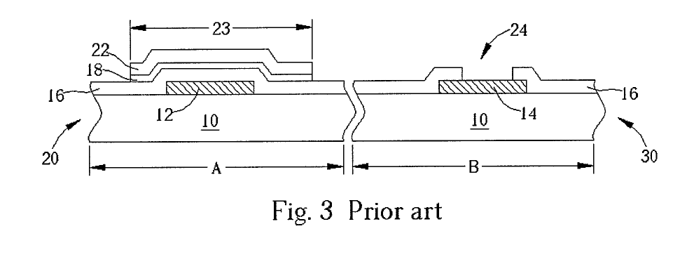

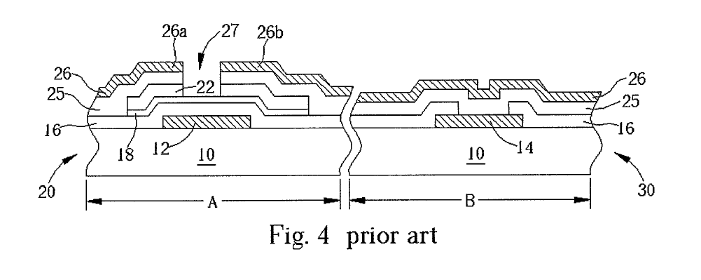

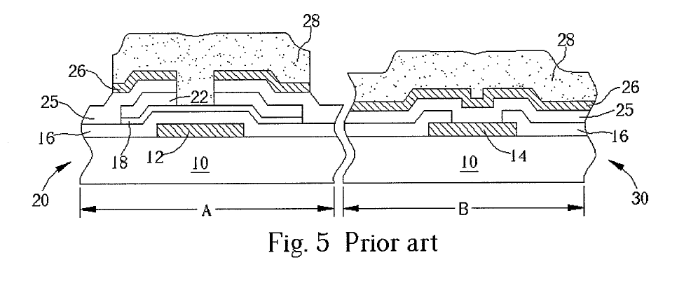

### DETAILED DESCRIPTION

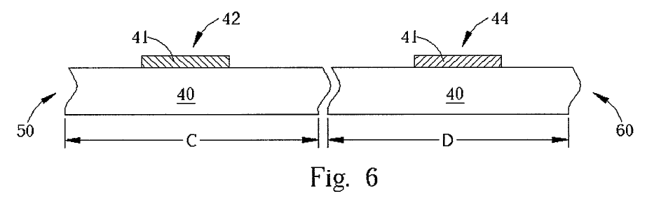

Please refer to FIG. 6 to FIG. 12. FIG. 6 to FIG. 12 are schematic diagrams of the present invention for fabricating a thin film transistor liquid crystal display. As shown in FIG. 6, the thin film transistor liquid crystal display is formed on a substrate 40. The substrate 40 is a transparent glass substrate made by highly purified silicon dioxide (SiO₂). At least one transistor area C is positioned on the surface of the substrate 40 and used for forming a transistor 50 thereon. At least one pad area D is positioned on the surface of the substrate 40, and used for forming a pad 60 thereon.

First, a first metal layer 41 is formed on the surface of the substrate 40 and patterned by a first mask. The first metal layer 41 is normally made of Chromium (Cr) or Titanium (Ti). After a photo-resist defined process and an etching process, a gate electrode 42 is formed in the transistor area C, and a pad electrode 44 is formed in the pad area D.

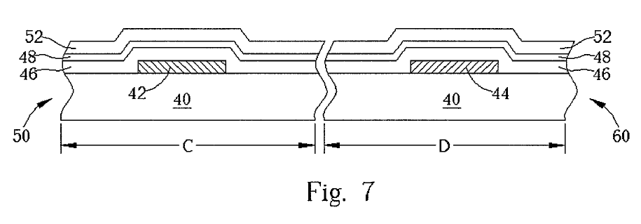

Referring to FIG. 7, a film-forming process, such as a chemical vapor deposition (CVD) process, is performed. An insulating layer 46 is then deposited on the substrate 40. The thickness of the insulating layer 46 is about 4000 angstrom. Simultaneously, a semiconductor layer 48 and a doped silicon layer 52 are formed on the surface of the insulating layer 46, respectively. The semiconductor layer 48 can be composed of amorphous silicon or poly silicon.

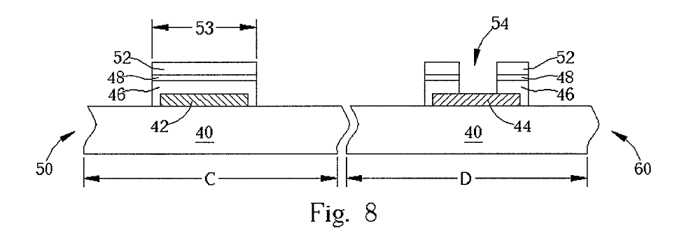

As shown in FIG. 8, a second mask is used to pattern the doped silicon layer 52, the semiconductor layer 48, and the insulating layer 46. After a photo-resist defining process and an etching process, an active area 53 is defined in the transistor area C, and a opening area is defined in the pad area D for forming a pad opening 54 in the opening area. Besides, this step is used to remove parts of the insulting layer 46, the semiconductor layer 48, and the doped silicon layer 52 positioned: (a) except the transistor area C, (b) except the pad area D, and (c) within the opening area. Therefore, the substrate 40 is exposed except the transistor area C and the pad area D, and then the pad opening 54 is formed in the pad area D so as to expose the pad electrode 44 in the pad opening 54.

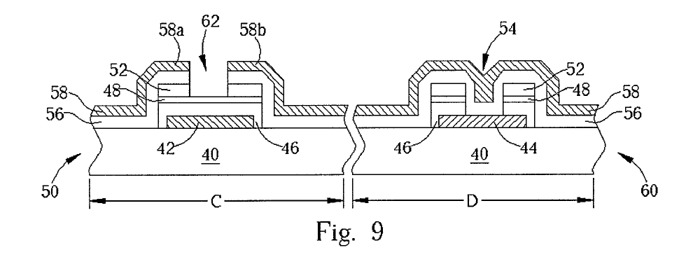

As shown in FIG. 9, a conductive layer 56 and a second metal layer 58 are deposited above the substrate 40. The conductive layer 56 can be transparent, and made of indium tin oxide(ITO) to act as a pixel electrode. A third mask is used to pattern the conductive layer 56 and the second metal layer 58. In the step, a channel 62 is defined in the transistor area C by removing a part of the second metal layer 58. The second metal layer 58 is then served as a mask for patterning the transparent conductive layer 56 and the doped silicon layer 52. The transparent conductive layer 56 and the doped silicon layer 52 are removed in the channel 52 so that the semiconductor layer 48 is exposed in the channel 62. The channel 62 divides the second metal layer 58, the transparent conductive layer 56, and the doped silicon layer 52 into two parts, and therefore, a source electrode 58a and a drain electrode 58b are formed.

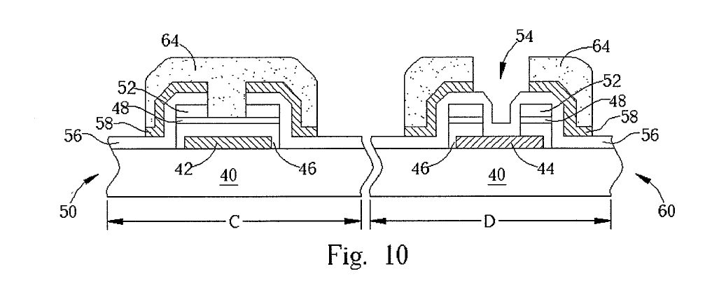

As shown in FIG. 10, a passivation layer 64 is deposited to cover the transistor 50 and the pad 60. Then, a fourth mask is used to pattern the second metal layer 58 and the passivation layer 64. After defining the pattern of the photo-resist layer (not shown), an etching process is employed to remove the passivation layer 64 and the second metal layer 58 positioned: (a) except the transistor area C, (b) except the pad area D, (c) in the opening 54. Therefore, the transparent conductive layer 56 is exposed within the opening 54, and outside the transistor area C and pad area D. The distance of the passivation layer 64 and the second metal layer 58 at the both sides of the opening 54 is about 35 micrometers.

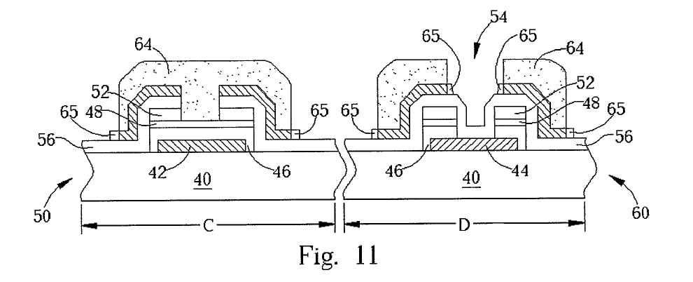

Usually, the passivation layer is made of silicon nitride or silicon oxide. After the above-mentioned etching process, a thermal oxidation process is performed. As shown in FIG. 11, the surface of the second metal later 58 is oxidized for forming an oxidation layer 65 on the sidewall surface of the second metal layer 58. The oxidation layer 65 is used to protect the second metal layer 58. The oxidation layer 65 can separate the surface of the second metal layer 58 and the liquid crystal molecule (not shown). The metal layer will not “pollute” the liquid crystal molecule, so the performance of the display will not be affected.

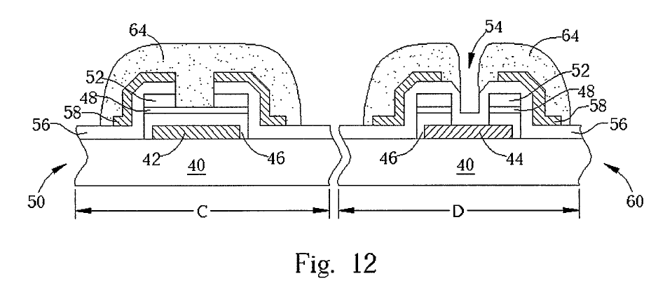

The passivation layer 64 also can be made of organic materials, and is formed as the same structure by the same process as shown in FIG. 10. Referring to FIG. 12, a thermal process is performed. The passviation layer 64 is re-flowed to cover the sidewall of the second metal layer 58. Therefore, the second metal layer 58 will not contact with the liquid crystal molecules. Another advantage for using organic materials as the passivation layer is that the organic materials can be formed on the substrate 40 by a spin-coating process. Therefore, the surface of the organic passivation layer will be flatter than the inorganic passivation layer.

The thickness of the passivation layer 64 is about 2 micrometers, and the width of the opening 54 is about 35 micrometers. The passivation layer 64 will not completely fill the opening 54 even though the passivation layer 64 is melted due to heat. Further, the resistance of the pad electrode 44 will not be increased.

Compared to the prior method for fabricating a thin film transistor liquid crystal display, the present invention can provide a simplifier process. Only 4 masks are used for reducing the manufacturing cost. The passivation layer can be consisted of organic or inorganic materials. Further, a thermal process or an oxidation reaction can be used to prevent the metal layer from polluting the liquid crystal molecules. Therefore, the image quality is enhanced and the quality of the display can also be improved to raise the competitiveness of the products.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of fabricating a thin film transistor display, the display being fabricated on a substrate, the substrate comprising a transistor area for forming a transistor and a pad area for forming a pad, the method comprising:
(1) forming a first metal layer on the surface of the substrate;
(2) patterning the first metal layer by a first mask to form a gate electrode in the transistor area and a pad electrode in the pad area;
(3) forming an insulating layer, a semiconductor layer and a doped silicon layer on the substrate;
(4) defining an opening area in the pad area, patterning the doped silicon layer, the semiconductor layer and the insulating layer by a second mask so as to remove the insulating layer, the semiconductor layer, the doped silicon layer positioned on the substrate (a) except the transistor area, (b) except the pad area and (c) within the opening area, the substrate thus being exposed in areas except the transistor area and the pad area, a pad opening being formed in the pad area, and the pad electrode being exposed in the pad opening;
(5) sequentially forming a transparent conductive layer and a second metal layer on the substrate, and filling the pad opening with the transparent conductive layer and the second metal layer;
(6) patterning the second metal layer by a third mask, defining a channel in the transistor area and removing the second metal layer in the channel, utilizing the second metal layer as a mask to pattern the transparent conductive layer and the doped silicon layer, and the transparent conductive layer and the doped silicon layer being removed in the channel to expose the semiconductor layer;
(7) forming a passivation layer on the substrate and covering the channel; and
(8) patterning the passivation layer and the second metal layer by a fourth mask, removing the passivation layer and the second metal layer positioned (a) except the transistor area, (b) except the pad area, and (c) in the pad opening, thus the transparent conductive layer being exposed in areas inside the pad opening, and outside the transistor area and the pad area.

2. The method of claim 1 wherein the sidewalls of the second metal layer are exposed in the transistor area and the pad area during the step (8), and the passivation layer is further heated by a thermal process to re-flow and cover the sidewalls of the second metal layer in the transistor area and the pad area after the step (8).

3. The method of claim 2 wherein the passivation layer is formed by an organic material.

4. The method of claim 1 wherein the method also comprises an oxidation reaction for forming an oxidation layer on the sidewall of the second metal layer to protect the second metal layer after the step (8).

5. The method of claim 4 where the passivation layer is formed by an inorganic material.

6. The method of claim 1 wherein the doped silicon layer is substantially aligned to the semiconductor layer and the insulating layer in the step (4), thus a part of the transparent conductive layer is deposited on the glass substrate.

7. The method of claim 1 wherein a source electrode and a drain electrode are formed and separated by the channel during the step (6).

8. The method of claim 1 wherein the substrate further comprises a capacitance area for forming a capacitor.

9. The method of claim 1 wherein the semiconductor layer is selected from a group consisted of an amorphous silicon layer and a poly-silicon layer.
